(19) United States
(12) Patent Application Publication
(10) Pub. No.: US 2006/0168803 A1
(43) Pub. Date: Aug. 3, 2006

(54) Layered board and manufacturing method of the same, electronic apparatus having the layered board

(75) Inventors: Takashi Kanda, Kawasaki (JP); Kenji Fukuzono, Kawasaki (JP); Manabu Watanabe, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 11/392,532

(22) Filed: Mar. 30, 2006

Related U.S. Application Data
(62) Division of application No. 10/998,062, filed on Nov. 29, 2004.

(30) Foreign Application Priority Data
May 31, 2004 (JP) 2004-160518

(51) Int. Cl. H05K 3/36

(52) U.S. Cl. 29/830

(57) ABSTRACT

A layered board includes a core layer that serves as a printed board, a buildup layer that is electrically connected to the core layer, the buildup layer including an insulation part and a wiring part, and a junction layer that electrically connects and bonds the core layer with the buildup layer, wherein the junction layer includes an adhesive and metallic particles contained in the adhesive, wherein each of the metallic particles has a first melting point, serves as a filler, and is plated with solder having a second melting point lower than the first melting point.

### CROSS REFERENCE TO RELATED APPLICATION

This application is a divisional application of U.S. application Ser. No. 10/998,062, filed Nov. 29, 2004, and claims the right of priority under 35 U.S.C.§119 based on Japanese Patent Application No. 2004-160518 filed on May 31, 2004, which is hereby incorporated by reference herein in its entirety as is fully set forth herein.

### BACKGROUND OF THE INVENTION

The present invention relates generally to a layered board and a manufacturing method of the same, and more particularly to a layered board that includes a core layer and a buildup layer at both surfaces of the core layer, which is also referred to as a “buildup board”, and a manufacturing method of the same.

The buildup boards have conventionally been used for laptop personal computers (“PCs”), digital cameras, servers, cellular phones, etc, to meet miniaturization and weight saving demands of electronic apparatuses. The buildup board uses a double-sided printed board or a multilayer printed board as a core, and adds an interfacially connected buildup layer (which is layers of an insulation layer and a wiring layer) to both surfaces or single surface of the core through the microvia technology. The double-sided lamination can maintain the warping balance. The microvia enables a through-hole connection to reduce a pad diameter and to make the board small and lightweight, the high-density wiring to reduce the cost, and the reduced via's diameter and length to improve electric characteristics, such as the parasitic capacity.

One known buildup board manufacturing method is a method for layering a buildup layer one by one on both surfaces of a core layer, as disclosed in Japanese Patent Application, Publication No. 2003-218519. In addition, Japanese Patent Application, Publication No. 2001-352171 and Multilayer Printed Wiring Board Internet <URL: http://industrial.panasonic.com/www-ctlg/ctlgj/qANE000_J.html> searched on May 23, 2004 teach to use conductive paste (or silver paste) to joint respective layers in Any Layer IVH (“ALIVH”) that applies to the entire layers an Inner Via Hole (“IVH”) structure that forms an interfacial connection of a multilayer board at an arbitrary location.

Other prior art includes, for example, Japanese Patent Application, Publication No. 2001-172606.

However, the conventional manufacturing method cannot satisfy the intended conductivity among layers in the buildup board, connection strength and reliability at the same time. For example, in order to apply the buildup board to a large tester board, such as an LSI wafer tester, it is necessary to make the coefficient of thermal expansion of a substrate close to that of the LSI (or silicon). Since it is known that the coefficient of thermal expansion of the buildup board largely depends upon the core material of the core layer, the core layer's coefficient of thermal expansion becomes much lower thin that of the buildup layer. When two types of layers having significantly different coefficients of thermal expansion are jointed together by silver paste that contains Ag filler in heat-hardeninig adhesive, silver can maintain the conductivity among layers but the entire adhesive force weakens, because silver itself does not have adhesive property. As a coefficient of thermal expansion differs greatly between the core layer and the buildup layer, the thermal stress and strain increase and thus the interfacial connection destroys disadvantageously.

As a solution for this problem, the instant inventors have considered use of solder instead of use of the conductive paste. Use of the solder would enhance the conductivity and adhesive force. However, the normal solder melts at a temperature much higher than the hardening temperature of the heat-hardeninig adhesive, and the thermal stress and strain increase when the temperature returns to the room temperature from that temperature. These increased thermal strain and stress would cause both layers to get damaged or deform, or interfacial layer to destroy. The instant inventors have then considered use of low-temperature solder, but the low-temperature solder remelts by heat, such as reflow, in the subsequent process.

### BRIEF SUMMARY OF THE INVENTION

Accordingly it is an exemplary object to provide a layered board, its manufacturing method, and an electronic apparatus having the layered board, which stabilize electric and mechanical characteristics of the interfacial connection.

A layered board according to one aspect of the present invention includes a core layer that serves as a printed board, a buildup layer that is electrically connected to the core layer, the buildup layer including an insulation part and a wiring part, and a junction layer that electrically connects and bonds the core layer with the buildup layer, wherein the junction layer includes an adhesive and metallic particles contained the adhesive, each of the metallic particles having a first melting point, serving as a filler, and being plated with solder having a second melting point lower than the first melting point. This layered board uses the low-temperature solder to lower the heat stress and strain at the time of joint. On the other hand, once the solder melts, the filler and solder work as an alloy, and the remelting temperature becomes higher than the second melting point because the filler makes the melting point of the junction layer higher than the second melting point. The metallic particles maintain the conductivity.

The core layer preferably has a coefficient of thermal expansion lower than that of the buildup layer. It is known that the core in the core layer largely dominates the coefficient of thermal expansion. For example, when the layered board is used as a tester board for LSI wafers, the layered board can have the coefficient of thermal expansion similar to that of silicon in the LSI wafer. The buildup layer is preferably provided at both sides of the core layer, so as to maintain the warping balance.

The layered board may further include an insulating adhesive that bonds the core layer with the buildup layer, so as to maintain the desired bonding force stronger than the filler's one. The second melting point is preferably equal to or lower than a melting point of the insulating adhesive, so as to provide joint using solder plating and bonding using the insulating adhesive.

The solder plated thickness is preferably 1 μm or greater. The solder plated thickness defines the bonding force. As the solder amount is small, the bonding force becomes low like the silver paste in the conventional ALIVH.

A manufacturing method according to another aspect of the present invention of a layered board that includes a core layer that serves as a printed board, and a buildup layer that is electrically connected to the core layer, the buildup layer including an insulation part and a wiring part includes arranging a conductive adhesive at a portion that electrically connects the core layer and the buildup layer, the conductive adhesive contains metallic particles in an adhesive each of metallic the particle having a first melting point, serving as a filler, and being plated with solder having a second melting point lower than the first melting point, and jointing the core layer and the buildup layer together by heating and compressing the buildup layer on the core layer on which the conductive agent is arranged. This manufacturing method can manufacture the layered board that exhibits the above operations.

A manufacturing method according to another aspect of the present invention of a layered board that includes a core layer that serves as a printed board, and a buildup layer that is electrically connected to the core layer, the buildup layer including an insulation part and a wiring part includes forming a perforation hole in an insulating adhesive sheet at a portion that electrically connects the core layer and the buildup layer, and arranging the insulating adhesive sheet on the core layer, wherein the arranging step fills the conductive adhesive in the perforation hole. This easy method can arrange the insulating adhesive and conductive adhesive on the core layer.

The manufacturing method preferably further includes the steps of determining whether the core layer is non-defective, and determining whether the buildup layer is non-defective, wherein the arranging step uses the core layer that has been determined to be non-defective, and the jointing step uses the buildup layer that has bee determined to be non-defective. The yield improves by determining the non-defectiveness before the manufacture of the layered board is completed and jointing the non-defective core layer and buildup layer together.

The manufacturing method may further include the step of adjusting a diameter of the metallic particle and/or a soldered thickness so that a remelting temperature of the conductive adhesive is higher than a melting temperature of the conductive adhesive. The remelting temperature is, for example, 250° C. or higher.

An electronic apparatus including the above layered board also constitutes one aspect of the present invention.

An electronic apparatus according to another aspect of the present invention includes two members having different coefficients of thermal expansion, and a junction layer that connects the two members, wherein the junction layer includes adhesive and metallic particles contained in the adhesive, wherein each of the metallic particles has a first melting point, serves as a filler, and is plated with solder having a second melting point lower than the first melting point. This electronic apparatus uses solder plating to reduce the thermal stress and strain that work between two members having different coefficients of thermal expansion when these members are jointed together and enables the filler to make the melting point higher after the joint. These two members are, for example, a core layer that serves as a printed board, and a buildup layer that is electrically connected to the core layer, the buildup layer including an insulation part and a wiring part, wherein the junction layer electrically connects and bonds the core layer with the buildup layer. Alternatively, these two components are, for example, an exoergic circuit device, and a heat spreader that transmits heat from the exoergic circuit device. This structure can reduce the temperature at the time of joint and prevent remelting when the exoergic circuit device, such as a CPU, heats.

The junction layer may includes hardener that contains one of carboxyl, amine and phenol, and organic acid that contains carboxylic acid of one of adipic acid, succinic acid and sebacic acid. Thereby, the solder's activation (or wetting performance) improves, i.e., the permeability into the core layer improves while preventing oxidation.

Other objects and further features of the present invention will become readily apparent from the following description of the preferred embodiments with reference to accompanying drawings.

### BRIEF DESCRIPTION OF THE DRAWINGS

FIG. 1 is a flowchart for explaining a manufacturing method of a layered board according to the present invention.

FIGS. 2A-2E are schematic sectional views of steps in FIG. 1.

FIG. 3 is a flowchart for explaining the step 1100 in FIG. 1 in detail.

FIGS. 4A-4D are schematic sectional views of steps in FIG. 3.

FIG. 5 is a flowchart for explaining the step 1200 in FIG. 1 in detail.

FIGS. 6A-6G are schematic sectional views of steps in FIG. 5.

FIGS. 7A-7G are schematic sectional views of steps in FIG. 5.

FIG. 8 is a graph showing a relationship between the remelting temperature the soldered thickness used for the conductive adhesive in the step 1500 in FIG. 1.

FIG. 9 is a plane view of one exemplary electronic apparatus to which a layered board shown in FIG. 2E is applied.

### DETAILED DESCRIPTION OF THE PREFERRED EMBODIMENTS

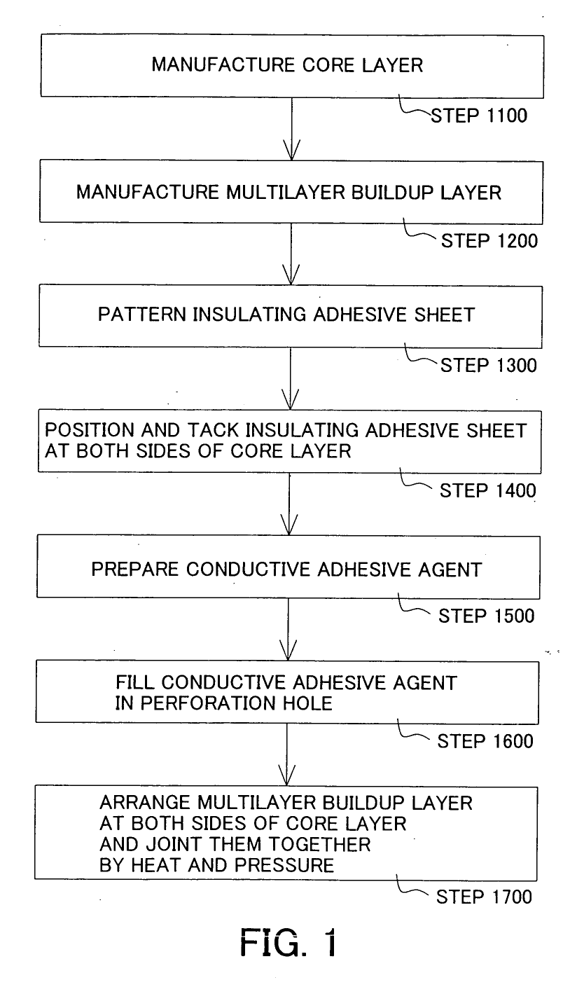

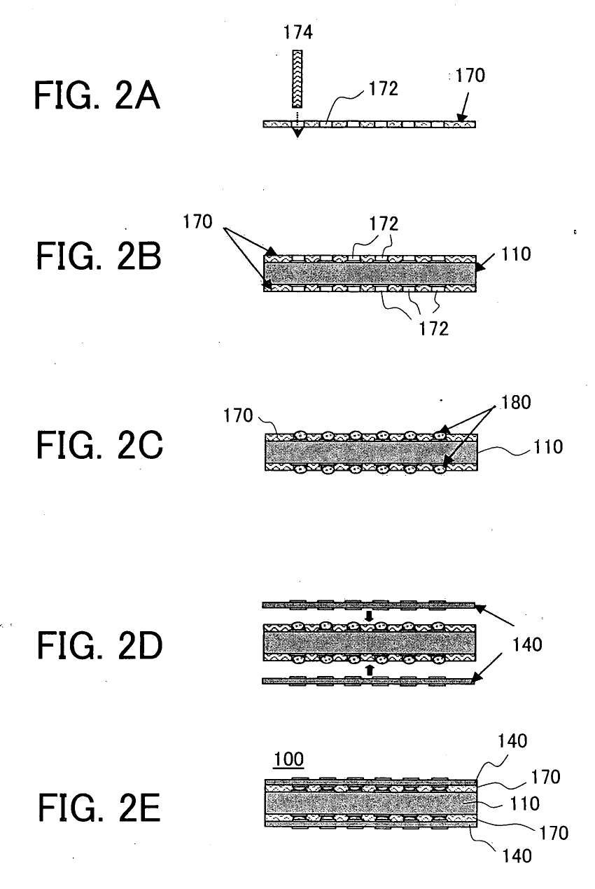

A description will be given of a manufacturing method of a layered board 100 according to one embodiment of the present invention. Here. FIG. 1 is a flowchart for explaining a manufacturing method of the layered board 100. FIG. 2 is a schematic sectional view of steps in FIG. 1. FIGS. 2A-2E are schematic sectional views of steps in FIG. 1.

First, a core layer 110 is manufactured (step 1100). The core layer 110 of the instant embodiment has a low coefficient of thermal expansion approximately equivalent to that of silicon (about 4.2×10⁻⁶/° C.), but the present invention does not limit the coefficient of thermal expansion. The core layer 110 has a rectangular or cylindrical shape in this embodiment, and four positioning holes (for example, at the corners of the rectangle) on the front and back surfaces. The core layer has a core and a through-hole, and may or may not include a layered structure on both sides of the core. In general, a pitch of the layered structure is greater than the interlaminar pitch of the buildup layer 140.

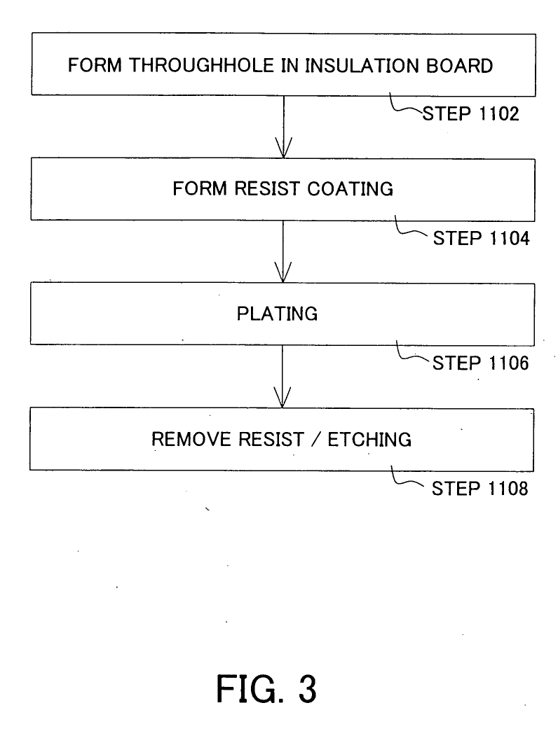

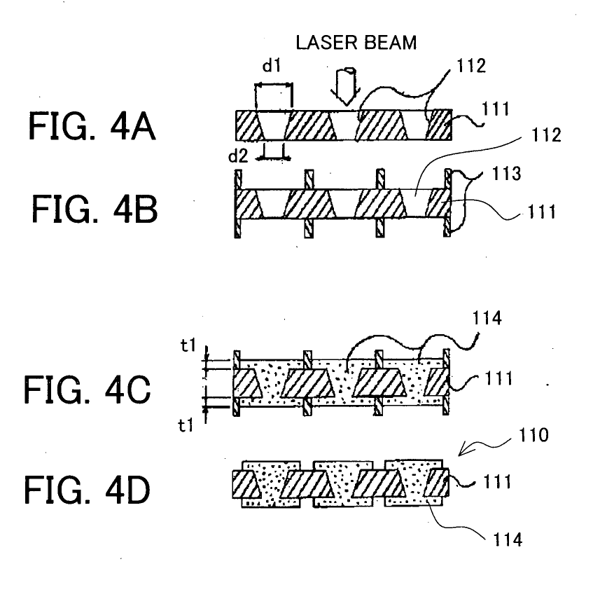

A detailed description will be given of the manufacture of the core layer 110, with reference to FIGS. 3 and 4. Here, FIG. 3 is a flowchart for explaining a manufacturing method of the core layer 110. FIGS. 4A-4D are schematic sectional views of steps in FIG. 3. A description will now be given of an exemplary manufacture method of the core layer 110 that does not have a layered structure.

First, a perforation hole 112 is formed, as shown in FIG. 4A, in an insulation board 111 through laser processing (step 1102). The insulation board 111 is made, for example, of glass cloth epoxy resin base material, glass cloth bsmaleimide-triazine resin base material, glass cloth poly phenylene ether resin base material, aramid polyimid liquid crystal polymer base material, etc. The perforation hole 112 serves as a through-hole. The insulation board 111 prepared in the instant embodiment is a thermoset epoxy resin base material with a thickness of about 50 μm. The laser processing uses, for example, a pulsed oscillation carbon dioxide laser processing unit, with the processing condition for example, of a pulsed energy of 0.1 to 1.0 mJ, a pulsed width of 1 to 100 μs, and the number of shots between 2 to 50. The perforation hole 112 made by the laser processing has a diameter d1 of about 60 μmΦ, and a diameter d2 of about 40 μmΦ. Thereafter, in order to remove residual resin in the perforation hole 112, the desmear process follows, such as an oxygen plasma discharge process a corona discharge process, a potassium permanganate process, etc. Moreover, the electroless plating is applied to the inside of the perforation hole 112 and the entire front and back surfaces of the insulation board 111. A coating thickness of the electroless plating is about 4500 Å.

Next, a dry film resist 113 is provided on front and rear surfaces of the insulation board 111 as shown in FIG. 4B (step 1104). This dry film resist 113 is, for example, of an alkali development type and photosensitivity. A thickness of the dry film resist 113 is, for example, about 40 μm. Exposure and development using the dry film resist 113 provides a desired pattern of resist coating.

The plating process follows as shown in FIG. 4C (step 1106). The plating process employs the DC electrolysis plating that utilizes the electroless plating layer provided in the step 1102 (FIG. 4A) as an electrode. The plating layer 114 is made of copper, tin, silver, solder, copper/tin alloy, copper/silver alloy, etc., and any type is applicable as long as it is metal that can be plated. The insulation board 111 with the dry film resist 113 obtained in the step 1104 is soaked in the plating bath tab. The plating layer 114 grows and increases its thickness on the inner-surface of the perforation hole 112 and on the entire front and back surfaces of the insulation board 111. As the thickness of the plating layer 114 increases, the plating layer 114 grows from the bottom surface part to the layer surface part of the perforation hole 112 and fills the bottom surface part of the of the perforation hole 112. The plating continues until the thickness t1 of the plating layer 114 on the front and back surfaces of the insulation board 111 becomes, for example, about 60 Lm, and the insulation substrate 111 including the perforation hole 112 has the flat front and back surfaces.

Thereafter, etching and resist removal follow (step 1108). The etching is to smoothen the rough plating layer 114 on both the front and back surfaces of the insulation board 111 and to adjust a thickness of the plating layer 114 on both the front and back surfaces. A usable etchant is copper chloride. The dry film resist 113 provided on the front and rear surfaces is then removed, as shown in FIG. 4D, by the release agent, which is, for example, an alkali release agent. As a result, the electroless plating exposes, which has been provided in step 1102, as a layer under the dry film resist 113 that has been removed. Then, this electroless plating is etched. A usable etchant is, for example, hydrogen persulfate.

The insulation board 111 may have a layered structure. For example, the insulation board 111 has second and third insulation boards at both sides of the first insulation board. The first insulation board is made of alamid or epoxy resin and set to have a thickness of about 25 μm and a heat decomposition temperature of about 500° C. The second and third insulation boards are made of thermoset epoxy resin, and set to have a thickness of about 12.5 μm and a heat decomposition temperature of about 300° C. The laser processing in the step 1102 can make different hole diameters of the perforation hole 112. The hole diameter in the second and third insulation boards having a lower heat decomposition is larger than that of the first insulation board. The perforation hole 112 has a section with an approximately X shape, rather than a trapezium shape shown in FIG. 4B. Thereby, the plating layer 114 grows from the upper and lower sides of the insulation board 111 at the same time, shortening the processing time period rather than growing only on one surface as shown in FIG. 4C.

Whether the core layer 110 is non-defective is determined before the core layer 110 and the buildup layer 140 are jointed together, and only the non-defective one is used for the step 1700.

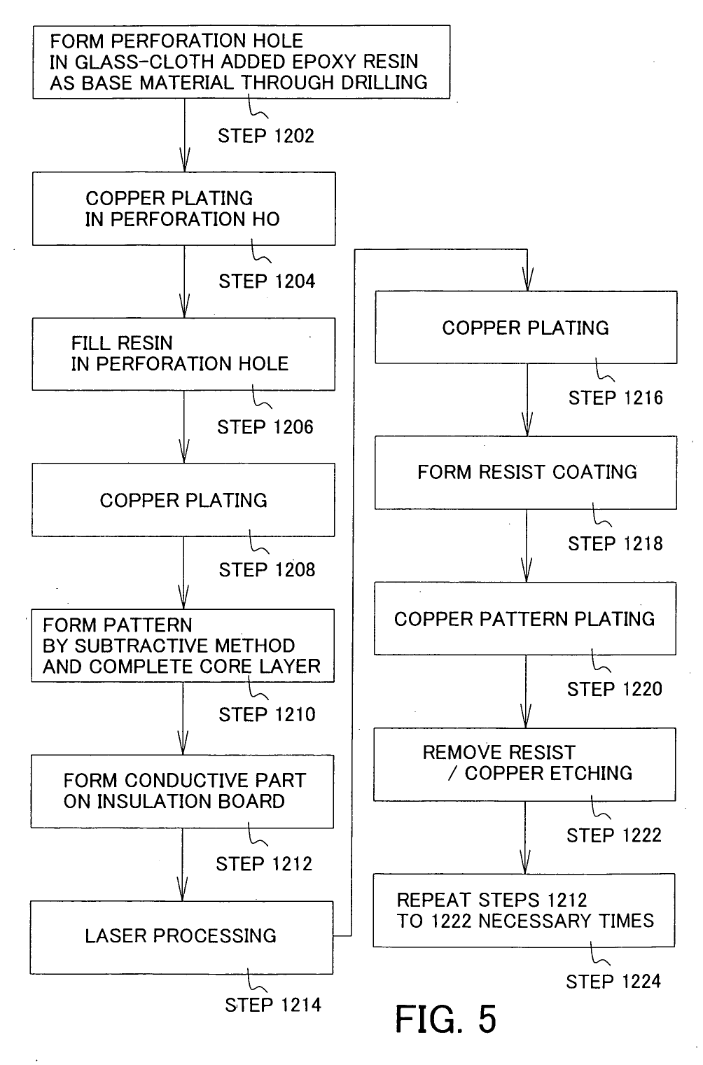

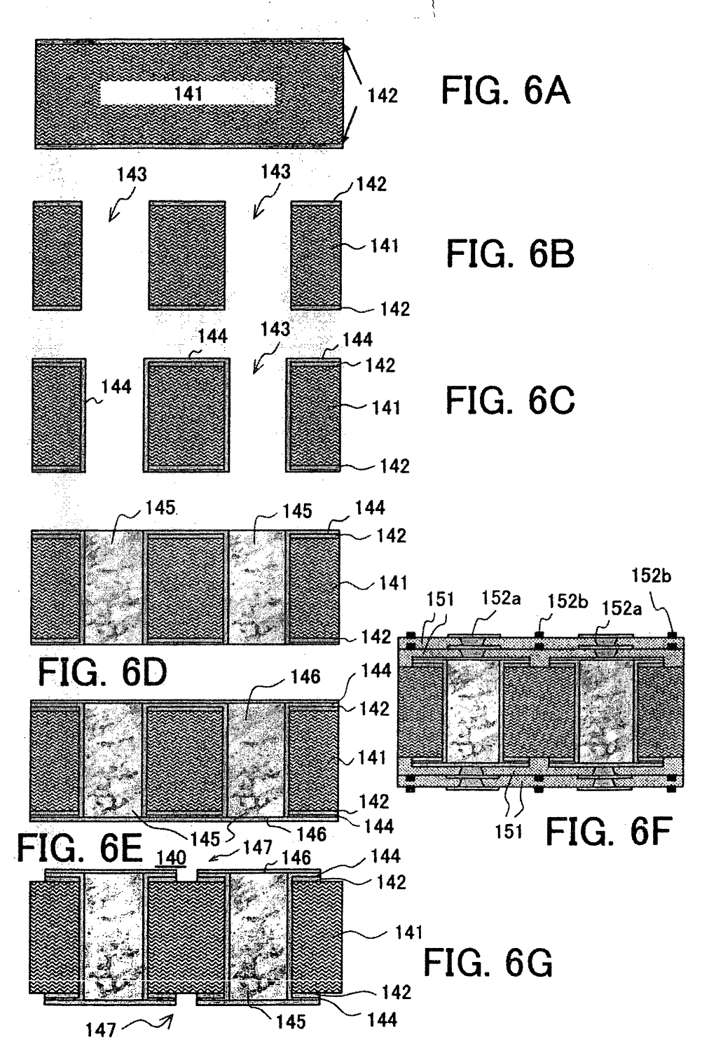

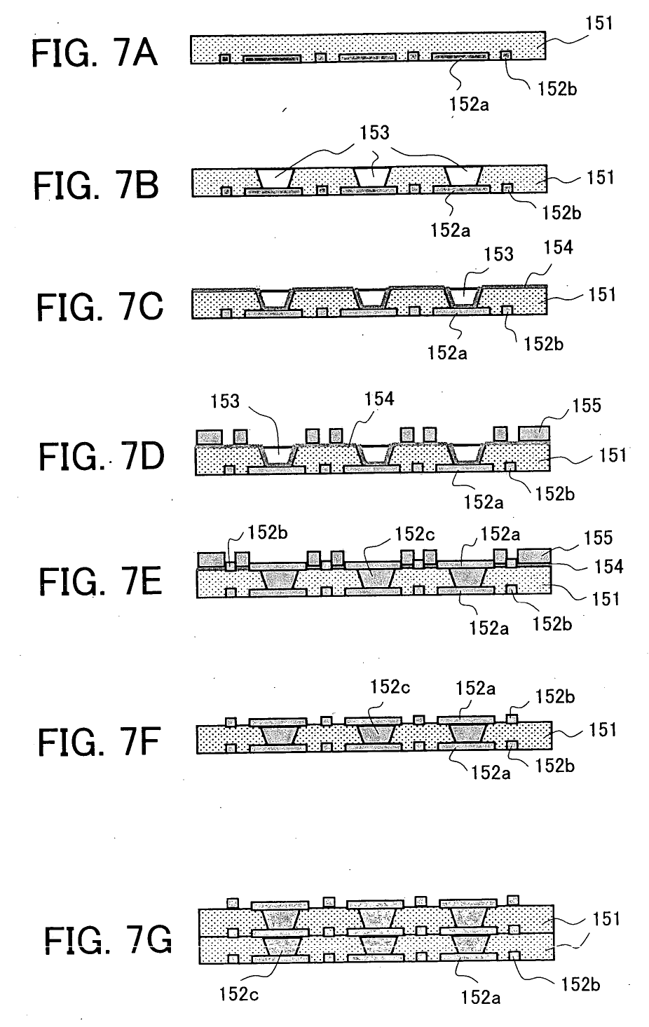

Next, the multilayer buildup layer 140 is manufactured (step 1200). The buildup layer 140 has a rectangular or cylindrical shape in this embodiment, and four positioning holes (for example, at the corners of the rectangle) on the front and back surfaces. The core layer has an insulating part and a wiring part, and is connected electrically to the core layer 110. The buildup layer 140 has a layered structure and may or may not include a core. A description will be given of a manufacture example of a buildup layer that includes the core, with reference to FIGS. 5-7. Here, FIG. 5 is a flowchart for explaining the manufacturing method of the buildup layer 140, and FIGS. 6A-6G are schematic sectional views of steps for manufacturing the core part in FIG. 5. FIGS. 7A-7G are schematic sectional views of steps for manufacturing, the layered part in FIG. 5.

The core part of the buildup layer 140 is initially produced.

As shown in FIG. 6A, epoxy resin 141 that contains glass cloth is prepared as a base material, and a perforation hole 143 is formed to maintain the conductivity between the front and back surfaces by drilling as shown in FIG. 6B (step 1202). Next, copper plating 114 is applied, as shown in FIG. 6C, to the inside of the perforation hole 143 (step 1204). Next, as shown in FIG. 6D, resin 145 fills the perforation hole 143 (step 1206). Next, copper plating 146 called lid plating is applied, as shown in FIG. 6E to a front surface (step 1208). Finally, the core layer 110 is completed, as shown in FIG. 6F, by forming a pattern 147 through etching according to the subtractive method (step 1210).

Next, the buildup layer 140 is completed by forming a layered part on both sides of the core part.

First, as shown in FIG. 7A, a conductive part 152a corresponding to a through-hole 112 of the core layer 110 and a conductive part 152b for a wiring part are formed in the insulation board 141 through copper plating (step 1212). Next, as shown in FIG. 7B, a hole 153 is formed that expose the copper plating 152a (step 1214). Next, as shown in FIG. 7C, an electroless plating 154 is applied (as shown in step 1216). Next, as shown in FIG. 7D, a resist coating 155 is formed which has openings in place corresponding to the conductive parts 152a and 152b (step 1218). Next, as shown in FIG. 7E, copper pattern plating is applied (step 1220). As a result, the conductive parts 152a and 152b are formed on the insulation board 151 and the hole 153 is filled with the conductive part 152c. Next follows resist removal and copper etching, as shown in FIG. 7F (step 1222). Next as shown in FIG. 7G, steps 1212 to 1222 are repeated to form the buildup layer 140 having the necessary number of layers. Finally, as shown in FIG. 6G, the buildup layer 140 is completed by repeating steps in FIGS. 7A-7G on the front and back surfaces of the core part shown in FIG. 6F. Whether the buildup layer 140 is non-detective is determined before the buildup layer 140 and the core layer 10 are jointed together, and only the non-defective one is used for the step 1700.

Next, as shown in FIG. 2A, the insulation adhesive sheet 170 is patterned (step 1300). The insulating adhesive sheet 170 is made, for example, of epoxy resin, and various types of insulating adhesive sheets are commercially available. The epoxy resin is heat-hardeninig adhesive and hardens at 150° C. However, the epoxy resin softens at about 80° C. and contacts the core layer 110, exhibiting a provisional fixation effect.

The height of the insulating adhesive sheet 170 determines an amount of the conductive adhesive 180. A perforation hole 172 is formed in the insulating adhesive sheet by a drill 174 at a position that electrically connects the core layer 110 with the buildup layer 140. While FIGS. 2A-2E provide the perforation holes 172 at regular intervals, this arrangement is exemplary. The insulating adhesive sheet 170 has a rectangular or circular shape in the instant embodiment, and four positioning holes (for example, at the corners of the rectangle) on the front and back surfaces.

Next, as shown in FIG. 2B, a pair of insulating adhesive sheet 170 is positioned and provisionally fixed at the both sides of the core layer 110 (step 1400). A perforation hole 172 is positioned at a position that electrically connects the core layer 110 to the buildup layer 140 or an electric connection pad part. This embodiment positions the core layer 110 and the insulating adhesive sheet 170 with each other by aligning their positioning holes and inserting pins into them. Thus, this embodiment utilizes mechanical positioning means, but the present invention does not limit the positioning means. For example, optical means and alignment marks may be used instead.

The adhesive sheet 170 is preliminarily heated, for example, up to about 80° C., and provisionally fixed onto the core layer 110. The positioning pins are pulled out after heating. While the instant embodiment positions and provisionally fixes the core layer 110 and the adhesive sheet 170 with each other, the buildup layer 140 may be tentatively fixed and fixed.

Next, the conductive adhesive 180 is prepared (step 150). The conductive adhesive contains metallic particles in an adhesive, such as epoxy resin. Each metallic particle has a first melting point, serves as a filler and is plated with solder having a second melting point lower than the first melting point. The epoxy resin adhesive as a base material in the conductive adhesive 180 of the present invention has the heat-hardening temperature is 150° C. The metallic particle, such as Cu, Ni, etc., has a high melting point and its melting point is preferably higher than the heat-hardening temperature of the adhesive as a base material, so as to prevent the adhesive from heat-hardening before the solder melts.

Thus, the conductive adhesive 180 is an adhesive that contains a conductive filler that includes as a core metallic particles with a high melting point, which is plated with low-temperature solder. Powders of metallic particles with various are commercially available. The instant embodiment applies electroless plating to a surface of a metallic particle. A plated thickness on the surface of the metallic particle is, for example, controllable by the soaking time period in the solution. Of course, the present invention does not limit the plating method.

The conductive adhesive 180 of the instant embodiment has some parameters to be satisfied, such as the conductivity, the melting temperature, the remelting temperature, and bonding force. The insufficient conductivity makes unstable the electric connection between the core layer 110 and the buildup layer 140, and deteriorates the electric characteristic of the layered board 100. The high melting temperature increases the thermal stress and strain that work between the core layer 110 and the buildup layer 140 or that affect the conductive adhesive 180, and both layers and the conductive adhesive 180 undesirably get damaged. Therefore, the low melting temperature is preferable. The low remelting temperature undesirably causes melting of the conductive adhesive 180 and weakens the bonding force and the conductivity when the subsequent process mounts another circuit device onto the layered board 100. Therefore, the remelting temperature is preferably 250° C. or higher. The bonding force is preferably stronger than the silver paste used for the conventional silver filler so as to maintain stable the conductivity and layered structure.

The conductivity of the conductive adhesive 180 depends upon the filler content and a solder amount. It is necessary to control these amounts in order to maintain the predetermined conductivity.

The melting temperature of the conductive adhesive 180 is the melting point of the plating. The instant embodiment uses the low-temperature solder consisting of Sn—Bi that has the melting temperature of 138° C.

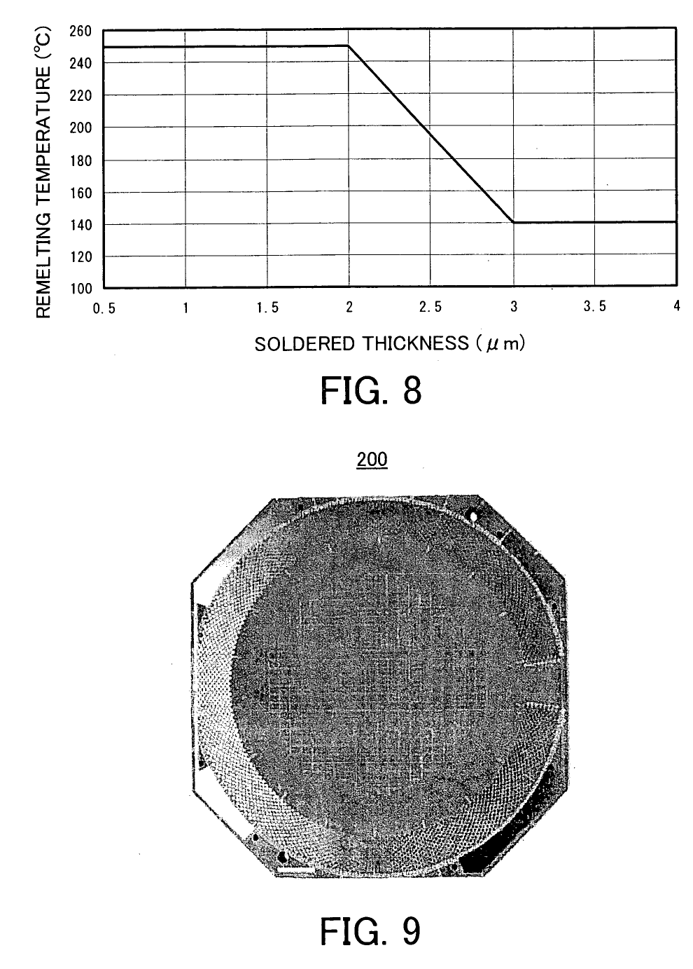

The remelting temperature of the conductive adhesive 180 is controllable by controlling the plated thickness and filler's particle diameter. Once the solder melts, the filler and the solder operate as an alloy, the melting temperature becomes higher by the filler. FIG. 8 shows a relationship between the Sn—Bi plated thickness and the remelting temperature when the filler (Cu) content is 90% and the particle diameter is between Φ20 to 40 μm. When the plated thickness exceeds 2 μm, solder insufficiently diffuses and thus remains. Therefore, the remelting temperature reduces down to about the melting point of Sn—Bi. Conversely, the plated thickness of 2 μm or smaller enables Sn—Bi to completely diffuse and makes the remelting temperature almost constant.

On the other hand, the plated thickness defines the bonding force of the conductive adhesive 180. The silver filler lowers the bonding force in the silver paste of the conventional ALIVH whereas the instant embodiment maintains the bonding force through the solder plating. The bonding force increases as the soldering amount increases. However, the large solder amount undesirably lowers the remelting temperature as discussed above. Therefore, the plated thickness should be determined so that the conductive adhesive 180 reconcile the predetermined junction strength with remelting temperature (reliability).

The graph shown in FIG. 8 moves to the right as the particle diameter is greater than 40 μm, and moves to the left as the particle diameter is smaller than 20 μm. In general, metallic particle having particle diameters of 100 μm or smaller, which is used as fillers, can maintain predetermined bonding strength if the Sn—Bi plated thickness is 1 μm or greater.

The graph shown in FIG. 8 changes according to used types of fillers and solders. While the conductive adhesive 180 of the instant embodiment has some parameters to be satisfied as discussed so as to make the coefficient of thermal expansion of the layered board 100 equivalent to that of silicon, the extent of the conductive adhesive 180's parameters to be satisfied varies if there is no such purpose. A type and thickness of the above solder plating, and filler's type, particle diameter and content are properly selected according to these parameters.

The conductive adhesive 180 includes hardener that contains one of carboxyl, amine and phenol, and organic acid that contains carboxylic acid of one of adipic acid, succinic acid and sebacic acid. Thereby, the solder's activation (or wetting performance) improves, i.e., the permeability into the core layer improves while preventing oxidation.

Next, as shown in FIG. 2C, the conductive adhesive 180 fills the perforation hole 172 (step 1600). This embodiment uses screen printing with a metal mask for filling, but the present invention does not limit a type of the filling method.

Next, the multilayer buildup layer 140 is positioned at both sides of the core layer 110, and jointed to the core layer through heat and pressure (step 1700). The positioning in the instant embodiment is similar to the positioning between the core layer 110 and the adhesive sheet 170, i.e., by aligning positioning holes in the adhesive sheet 170 with positioning holes in the buildup layer 140 and inserting pins into these positioning holes. The heating and compression are conducted through pressing under a vacuum environment, as referred to as a vacuum laminate.

The instant embodiment not only determines whether the core layer 110 is non-defective but also determines whether the buildup layer 140 is non-defective, before jointing the core layer 110 and the buildup layer 140 together, and uses only the non-defective core layer 110 and the non-defective buildup layer 140 for the joint in the step 1700. The yield improves by determining non-defectiveness before the manufacture of the layered board 100 is completed.

The instant embodiment uses the low-temperature solder, and the solder melts at a melting point lower than that of normal solders. The lower melting point reduces the thermal stress and strain that work between the core layer 110 and the buildup layer 140 when the temperature returns to the room temperature from the high temperature, preventing damages of both layers and junction layer. In addition, the high melting point metallic particles makes the melting point of the conductive adhesive 180 higher than that of the low-temperature solder, and thus makes the remelting temperature higher. As a result, the conductive adhesive 180 does not remelt or the reliability of adhesion does not reduce even when the subsequent process mounts a circuit device. The metallic particles maintain the conductivity between the core layer 110 and the buildup layer 140.

FIG. 2E shows a completed layered board 100. The buildup layers 170 are arranged at both sides of the core layer 110 and maintain the warp balance.

FIG. 9 shows a top view of a tester board 200 for LSI wafers, to which the layered board 100 is applied.

### EXAMPLE 1

The conductive adhesive 180 used a Cu core (with a particle diameter Φ between 20 μm and 40 μm) and Sn—Bi solder for its surface (with a plated thickness of 2 μm). The coefficients of thermal expansion of the core layer 110 and the buildup layer 140 were 1 ppm/° C. and 20 ppm/° C., respectively. It was confirmed that the completed layered board has the coefficient of thermal expansion of 3 ppm/° C. and the remelting temperature of the junction part is 250° C. or higher.

The conductive adhesive 180 of the present invention is broadly applicable to joints of two members having different coefficients of thermal expansion in an electronic apparatus. For example these two members are an exoergic circuit device, such as a CPU, and a transmission member, such as a heat spreader and a heat sink, which transmits the heat from the exoergic circuit device. This structure can lower the temperature for junction, and prevents remelting when the exoergic circuit device heats. Epoxy resin used for the conductive adhesive 180 strongly joints the CPU and transmission member together efficiently transmits the heat from the CPU to the transmission member, and radiates the CPU.

Further, the present invention is not limited to these preferred embodiments, and various variations and modifications may be made without departing from the scope of the present invention. For example, the electronic apparatus of the present invention is not limited to tester for LSI wafers, but is broadly applicable to laptop PCs, digital cameras, servers, and cellular phones.

Thus the present invention can provide a layered board, its manufacturing method, and an electronic apparatus having the layered board, which stabilize electric and mechanical characteristics of the interfacial connection.

What is claimed is:

1. A manufacturing method of a layered board that includes a core layer that serves as a printed board, and a buildup layer that is electrically connected to said core layer, said buildup layer including an insulation part and a wiring part, said manufacturing method comprising the steps of:
arranging a conductive adhesive at a portion that electrically connects the core layer and the buildup layer, the conductive adhesive contains metallic particles in an adhesive each of metallic the particle having a first melting point, serving as a filler, and being plated with solder having a second melting point lower than the first melting point, and jointing the core layer and the buildup layer together by heating and compressing, the buildup layer on the core layer on which the conductive agent is arranged.

2. A manufacturing method of a layered board that includes a core layer that serves as a printed board, and a buildup layer that is electrically connected to said core layer said buildup layer including an insulation part and a wiring part, said manufacturing method comprising the steps of:
forming a perforation hole in an insulating adhesive sheet at a portion that electrically connects the core layer and the buildup layer; and
arranging the insulating adhesive sheet on the core layer, wherein said arranging step fills the conductive adhesive in the perforation hole.

3. A manufacturing method according to claim 1, further comprising the steps of:
determining whether the core layer is non-defective; and
determining whether the buildup layer is non-defective, wherein said arranging step uses the core layer that has been determined to be non-defective, and said jointing step uses the buildup layer that has bee determined to be non-defective.

4. A manufacturing method according to claim 1, further comprising the step of adjusting a diameter of the metallic particle and/or a soldered thickness so that a remelting temperature of the conductive adhesive is higher than a melting temperature of the conductive adhesive.

5. A manufacturing method according to claim 1, wherein the remelting temperature is 250° C. or higher.
